(19) United States
(12) Patent Application Publication
(10) Pub. No.: US 2009/0085125 A1
(43) Pub. Date: Apr. 2, 2009

(54) MOS transistor and CMOS transistor having strained channel epi layer and methods of fabricating the transistors

(75) Inventors: Ki-Chul Kim, Suwon-si (KR); Hong-jae Shin, Seoul (KR); Moon-han Park, Yongin-si (KR); Hwa-sung Rhee, Seongnam-si (KR); Jung-deog Lee, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/285,044

(22) Filed: Sep. 29, 2008

(30) Foreign Application Priority Data
Sep. 28, 2007 (KR) 10-2007-0098400

(51) Int. Cl. H01L 27/092; H01L 29/94

(52) U.S. Cl. 257/369; 257/402; 257/E27.062; 257/E29.345

(57) ABSTRACT

Provided are a metal oxide semiconductor (MOS) transistor and a complementary MOS (CMOS) transistor each having a strained channel epi layer, and methods of fabricating the transistors. The MOS transistor may include at least one active region defined by an isolation structure formed in a substrate. At least one channel trench may be formed in a part of the at least one active region. At least one strained channel epi layer may be in the at least one channel trench. At least one gate electrode may be aligned on the at least one strained channel epi layer. Sources/drains may be arranged in the at least one active region along both sides of the at least one strained channel epi layer.

### PRIORITY STATEMENT

This application claims priority under U.S.C. §119 to Korean Patent Application No. 10-2007-0098400, filed on Sep. 28, 2007, in the Korean Intellectual Property Office (KIPO), the entire contents of which are incorporated herein by reference.

### BACKGROUND

1. Field

Example embodiments relate to a metal oxide semiconductor (MOS) transistor, a complementary MOS (CMOS) transistor, and methods of fabricating the transistors, and more particularly, to a MOS transistor and a CMOS transistor each having a strained channel, and methods of fabricating these transistors.

2. Description of the Related Art

Metal oxide semiconductor (MOS) transistors are devices that have been used in the electronic industry. The carrier mobility of an MOS transistor may be an important parameter that directly affects output current and switching performance. In order to improve the carrier mobility of an MOS transistor, various techniques of straining a channel of an MOS transistor have been introduced. In general, electron mobility may be improved in a tensile strained channel and hole mobility may be improved in a compressive strained channel.

A tensile stress liner may be formed on an N-channel MOS (NMOS) transistor in order to improve the electron mobility of the NMOS transistor, and a compressive stress liner may be formed on a P-channel MOS (PMOS) transistor in order to improve the hole mobility of the PMOS transistor. However, when such a stress liner is used, there may be limited improvement in the electron mobility because causing a channel region to be appropriately strained may be difficult. Further, if a contact hole is formed in the stress liner during a subsequent process, the stress in the stress liner may be relieved, thereby decreasing the strain in the channel region from being appropriately strained.

### SUMMARY

Example embodiments provide a metal oxide semiconductor (MOS) transistor and a complementary MOS (CMOS) transistor whose channels may be appropriately strained, and methods of fabricating these transistors.

According to example embodiments, a MOS transistor may include at least one active region defined by an isolation structure in a substrate, at least one channel trench in a part of the at least one active region, at least one strained channel epi layer in the at least one channel trench, at least one gate electrode aligned on the at least one channel epi layer, and a plurality of sources/drains in the at least one active region along both sides of the at least one channel epi layer.

According to example embodiments, a CMOS transistor may include at least two of the MOS transistors of example embodiments, wherein the at least two MOS transistors are at least one n-type MOS transistor and at least one p-type MOS transistor, and wherein the at least one active region is at least one N active region and at least one P active region; the at least one channel trench is an N-channel trench and a P-channel trench in parts of the at least one N active region and the at least one P active region, respectively; the at least one channel epi layer is a tensilely strained N-channel epi layer in the N-channel trench and a compressively strained P-channel epi layer in the P-channel trench; the at least one gate electrode is an N gate electrode and a P gate electrode aligned on the N-channel epi layer and the P-channel epi layer, respectively; and the plurality of sources/drains are N sources/drains in the at least one N active region along both sides of the N-channel epi layer, and P sources/drains in the at least one P active region along both sides of the P-channel epi layer.

According to example embodiments, a method of fabricating a MOS transistor may include defining an active region by forming an isolation structure in a substrate, forming a hard mask layer having an opening across an upper part of the active region, forming a channel trench in the active region by etching the active region using the hard mask layer as a mask, forming a strained channel epi layer in the channel trench, forming a gate electrode on the strained channel epi layer in order to fill at least a lower part of the opening, removing the hard mask layer, and forming sources/drains in active regions along both sides of the strained channel epi layer.

According to example embodiments, a method of fabricating a CMOS transistor may include defining an N active region and a P active region by forming an isolation structure in a substrate, forming a hard mask layer on the active regions, forming a first opening in the hard mask layer across an upper part of the N active region, forming an N-channel trench in the N active region by etching the N active region using the hard mask layer as a mask, forming a tensilely strained N-channel epi layer in the N-channel trench, forming a second opening in the hard mask layer across an upper part of the P active region, forming a P-channel trench in the P active region by etching the P active region using the hard mask layer as a mask, forming a compressively strained P-channel epi layer in the P-channel trench, forming a plurality of gate electrodes on the channel epi layers in order to fill at least lower parts of the openings, removing the hard mask layer, forming N sources/drains in N active regions along both sides of the N-channel epi layer, and forming P sources/drains in P active regions along both sides of the P-channel epi layer.

### BRIEF DESCRIPTION OF THE DRAWINGS

Example embodiments will be more clearly understood from the following detailed description taken in conjunction with the accompanying drawings. FIGS. 1A-5 represent non-limiting, example embodiments as described herein.

FIGS. 1A-1C are plan views sequentially illustrating a method of fabricating a complementary metal oxide semiconductor (CMOS) transistor according to example embodiments;

FIGS. 2A-2J are cross-sectional views sequentially illustrating the method of FIGS. 1A-1C;

FIGS. 3A-3F are cross-sectional views sequentially illustrating a method of fabricating a CMOS transistor according to example embodiments;

FIGS. 4-4E are cross-sectional views sequentially illustrating a method of fabricating a CMOS transistor according to example embodiments; and

FIG. 5 is a cross-sectional view illustrating a CMOS transistor according to example embodiments.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Example embodiments will now be described more fully with reference to the accompanying drawings, in which example embodiments may be shown. These example embodiments may, however, be embodied in many different forms and should not be construed as being limited to the embodiments set forth herein. Rather, these embodiments are provided so that this disclosure will be thorough and complete and will fully convey the concept of example embodiments to those skilled in the art. The same reference numerals represent the same elements throughout the drawings.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

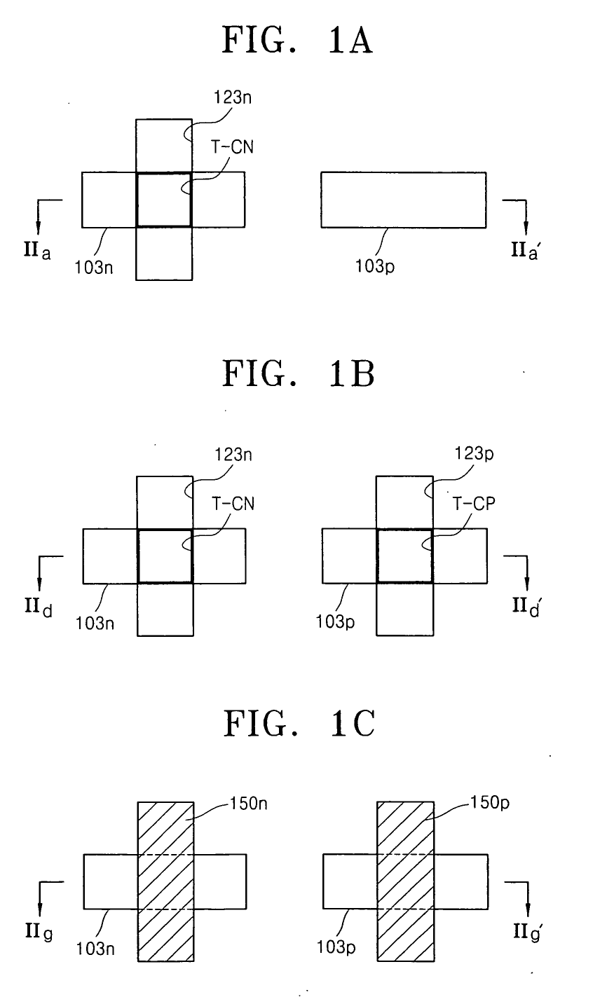

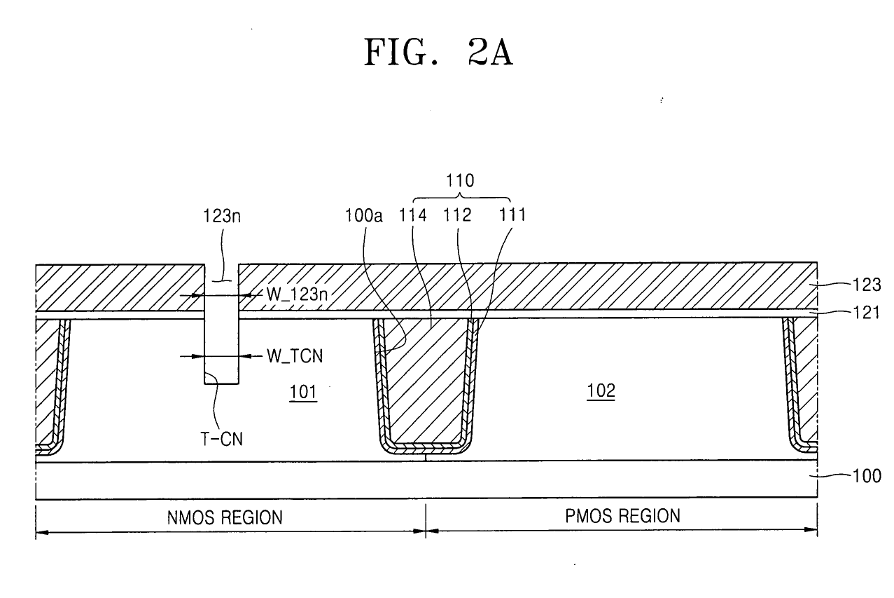

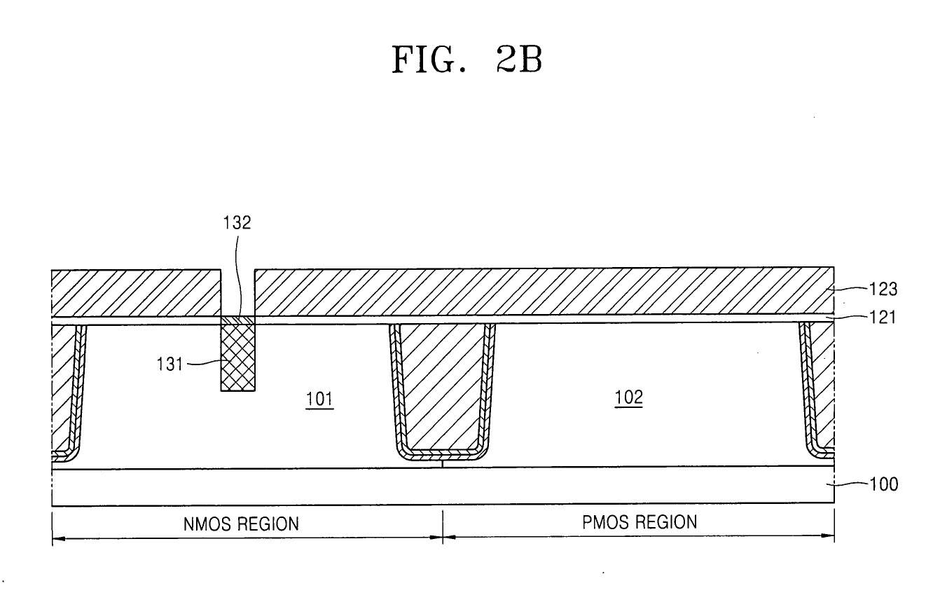

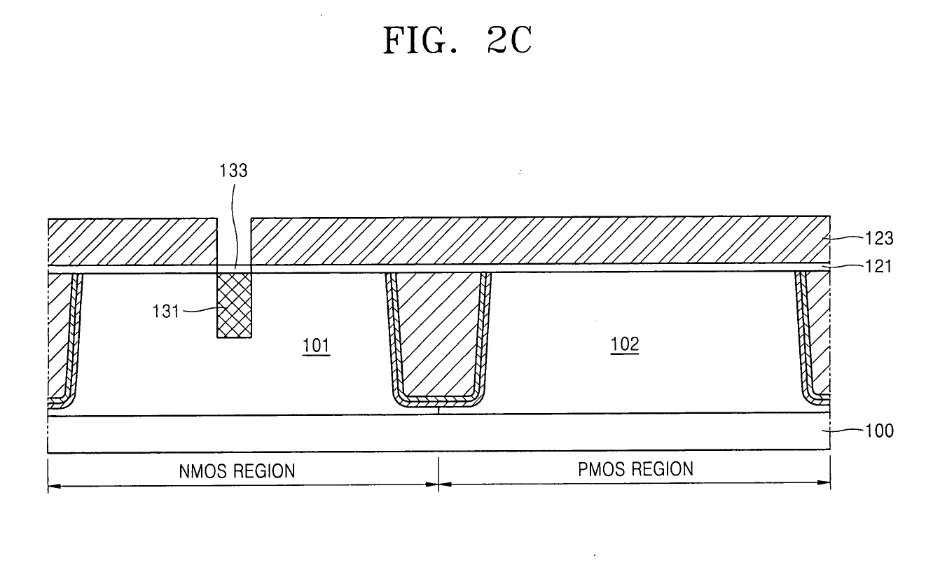

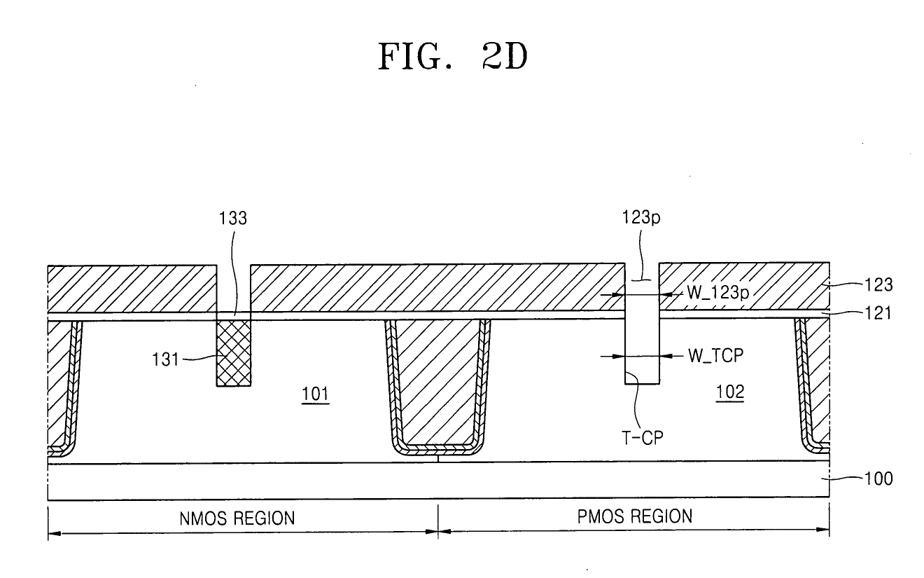

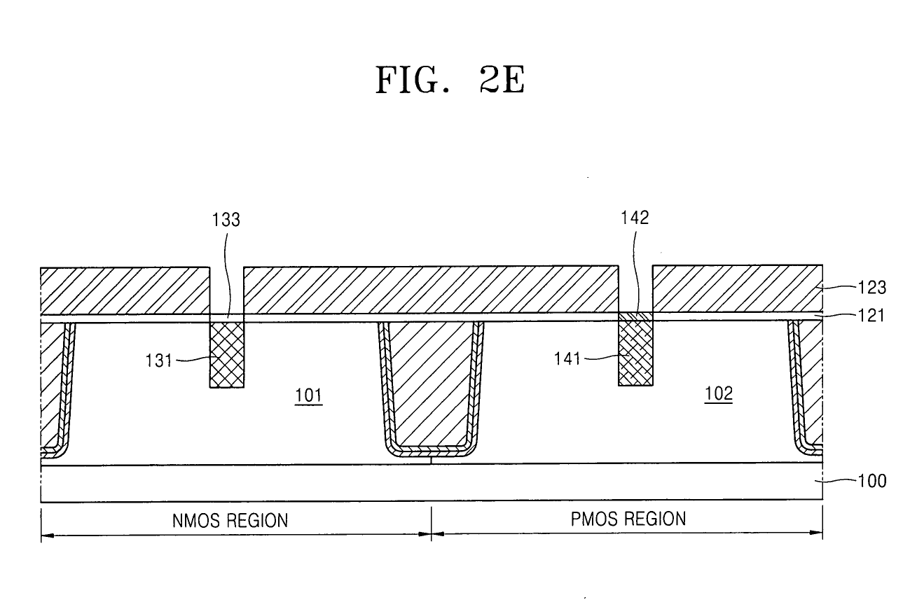

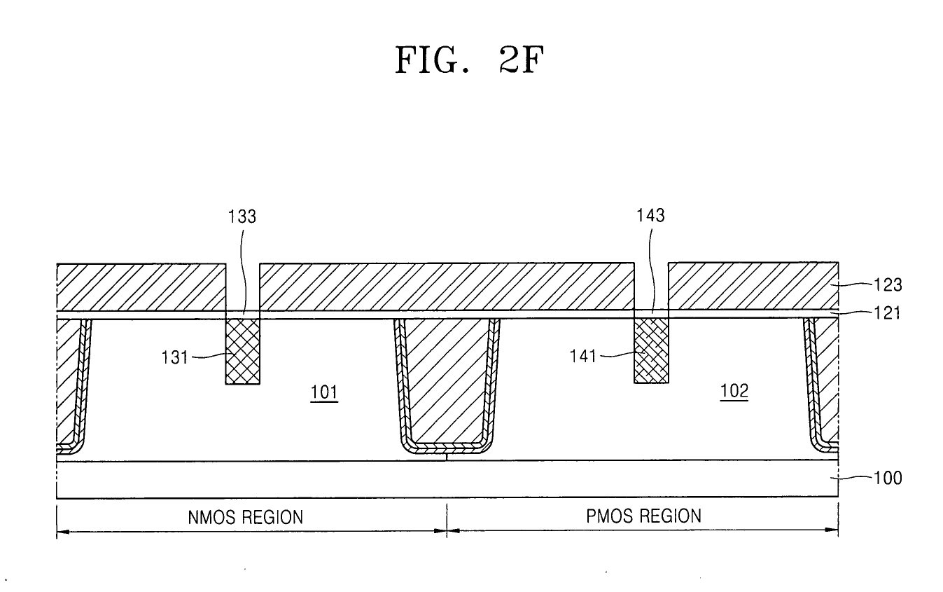

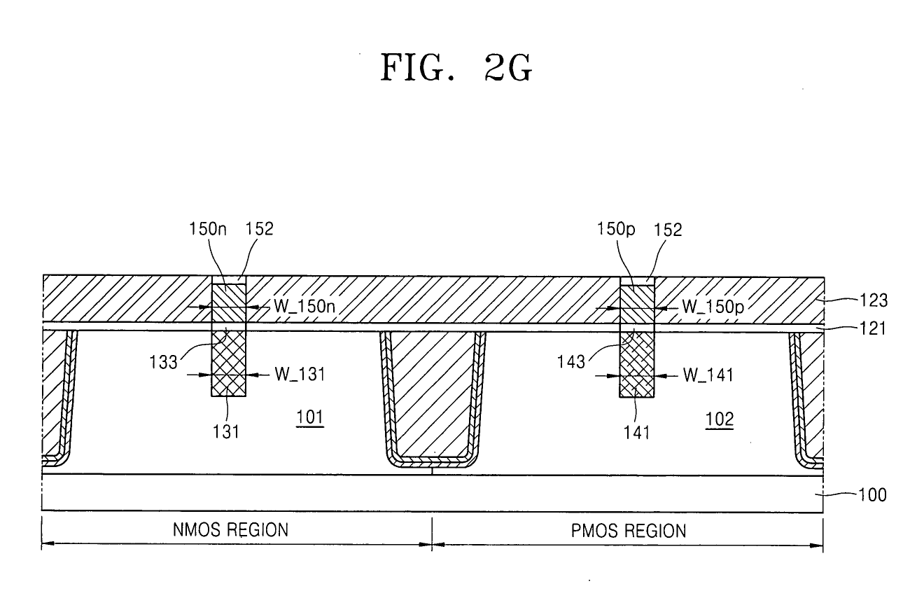

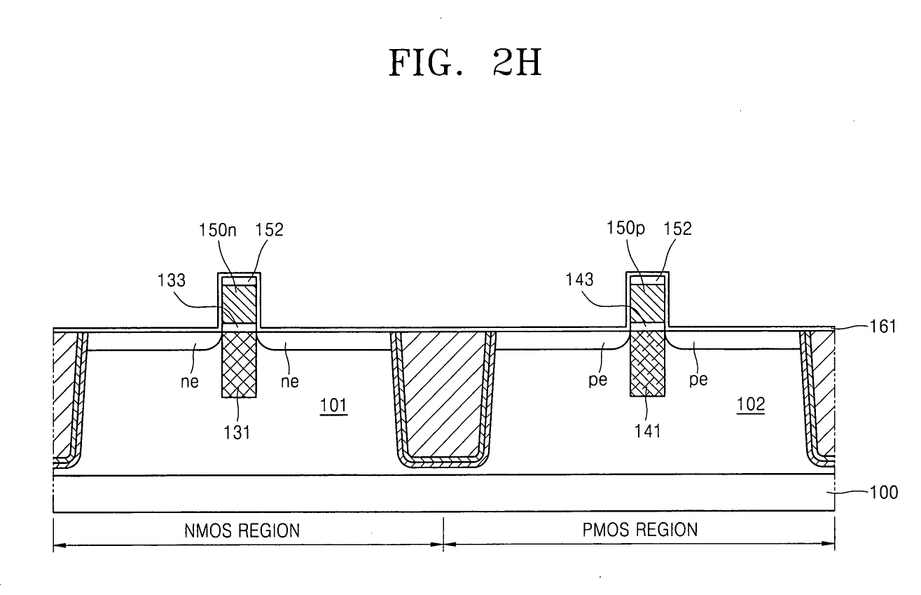

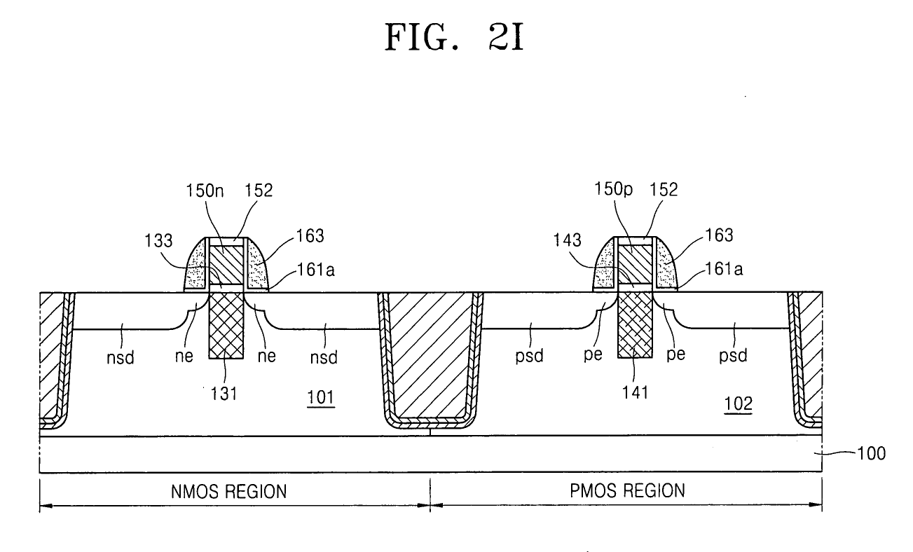

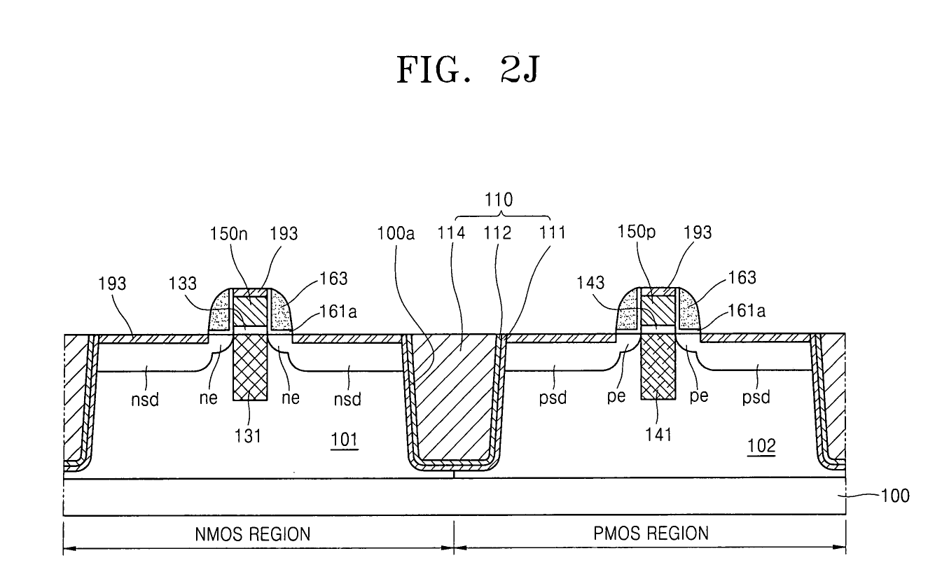

FIGS. 1A-1C are plan views sequentially illustrating a method of fabricating a complementary metal oxide semiconductor (CMOS) transistor according to example embodiments. FIGS. 2A-2J are cross-sectional views illustrating the method of FIGS. 1A-1C. FIG. 2A is a cross-sectional view taken along the line IIₐ-II_{a′} of FIG. 1A, FIG. 2D is a cross-sectional view taken along the line II_{d}-II_{d′} of FIG. 1B, and FIG. 2G is a cross-sectional view taken along the line II_{g}-II_{g′} of FIG. 1C.

Referring to FIGS. 1A and 2A, a substrate 100 having an N-channel MOS (NMOS) region and a P-channel MOS (PMOS) region may be prepared. The substrate 100 may be a silicon single crystal layer of a silicon single crystal substrate or a silicon-on-insulator (SOI) substrate. In the substrate 100, an isolation structure 110 may be formed in order to respectively define an N active region 103n and a P active region 103p in the NMOS region and the PMOS region. The isolation structure 110 may be obtained by forming an isolation trench 100a in the substrate 100, sequentially depositing an oxide layer liner 111 and a nitride layer liner 112 in the isolation trench 100a, filling the isolation trench 100a with an isolation layer 114, and then, planarizing the isolation layer 114 and the liners 111 and 112.

A P well 101 may be formed by implanting p-type impurities into the NMOS region, and an N well 102 may be formed by implanting n-type impurities into the PMOS region. A pad oxide layer 121 and a hard mask layer 123 may be sequentially formed on the substrate 100. The hard mask layer 123 may be a silicon nitride layer. A first opening 123n may be formed in the hard mask layer 123 across an upper part of the N active region 103n by patterning the hard mask layer 123 and the pad oxide layer 121 using a first photoresist pattern (not shown). A part of the N active region 103n and an upper surface of the isolation structure 110 around the N active region 103n may be exposed via the first opening 123n.

The first photoresist pattern may be removed, and the N active region 103n may be selectively etched using the hard mask layer 123 as a mask in order to form an N-channel trench T_CN in the N active region 103n. The N-channel trench T_CN may be formed using anisotropic etching. The width W_TCN of the N-channel trench T_CN may be substantially equal to the width W_123n of the first opening 123n. The N-channel trench T_CN may be formed to a depth of about 500 Å to about 1000 Å.

Referring to FIG. 2B, a strained N-channel epi layer 131 may be formed in the N-channel trench T_CN. The N-channel epi layer 131 may be a tensilely strained epi layer, and in example embodiments, the electron mobility in the N-channel epi layer 131 may increase. Also, after forming the N-channel trench T_CN, the N-channel epi layer 131 may be selectively or locally formed in the N-channel trench T_CN, thereby reducing manufacturing costs for growth of the N-channel epi layer 131.

The tensilely strained N-channel epi layer 131 may be a SiC epi layer that may be epitaxially grown from an exposed part of the substrate 100 in the N-channel trench T_CN. The SiC epi layer may have a crystal lattice smaller than that of silicon included in the substrate 100, and thus, may be tensilely strained. The N-channel epi layer 131 may be grown in such a manner than an upper surface thereof may be substantially level with that of the substrate 100.

An N-channel silicon cap 132 may be formed on the N-channel epi layer 131. The N-channel silicon cap 132 may be an epi layer that may be epitaxially grown from the N-channel epi layer 131. The N-channel silicon cap 132 may be formed to a thickness of about 10 Å to about 100 Å. The epi layers 131 and 132 may be formed using selective epi growing and may be continuously formed in the same epi growing equipment. Referring to FIG. 2C, an N gate oxide layer 133 may be formed directly on the N-channel epi layer 131 by thermally oxidizing the N-channel silicon cap 132

Referring to FIGS. 1B and 2D, the hard mask layer 123 and the pad oxide layer 121 may be again patterned using a second photoresist pattern (not shown) in order to form a second opening 123p in the hard mask layer 123 across the upper part of the P active region 103p. A part of the P active region 103p and an upper surface of the isolation structure 110 around the P active region 103p may be exposed via the second opening 123p. A P-channel trench T_CP may be formed in the P active region 103p by removing the second photoresist pattern and selectively etching the P active region 103p by using the hard mask layer 123 as a mask. The P-channel trench T_CP may be formed using anisotropic etching. The width W_TCP of the P-channel trench T_CP may be substantially equal to the width W_123p of the second opening 123p. The P-channel trench T_CP may be formed to a depth of about 500 Å to about 1,000 Å.

Referring to FIG. 2E, a strained P-channel epi layer 141 may be formed in the P-channel trench T_CP. The P-channel epi layer 141 may be a compressively strained epi layer, and in example embodiments, the hole mobility in the P-channel epi layer 141 may increase. The compressively strained P-channel epi layer 141 may be a SiGe epi layer that may be epitaxially grown from an exposed part of the substrate 100 in the P-channel trench T_CP. The SiGe epi layer may have a crystal lattice greater than that of silicon included in the substrate 100, and thus, may be compressively strained. The P-channel epi layer 141 may be grown in such a manner that an upper surface thereof may be substantially level with that of the substrate 100.

A P-channel silicon cap 142 may be formed on the P-channel epi layer 141. The P-channel silicon cap 142 may be an epi layer that is epitaxially grown from the P-channel epi layer 141. The P-channel silicon cap 142 may be formed to a thickness of about 10 Å to about 100 Å. The epi layers 141 and 142 may be formed using selective epi growing and may be continuously formed in the same epi growing equipment. When the epi layers 141 and 142 are grown, the N active region 103n may be covered with the hard mask layer 123 and the N gate oxide layer 133. Therefore, no epi layer may be grown on the N active region 103n. Referring to FIG. 2F, a P gate oxide layer 143 may be formed directly on the P-channel epi layer 141 by thermally oxidizing the P-channel silicon cap 142.

Referring to FIGS. 1C and 2G, the openings 123n and 123p may be filled with a gate conductive layer (not shown), and the gate conductive layer may be planarized until a surface of the hard mask layer 123 may be exposed. The planarized gate conductive layer may be etched back in order to form an N gate electrode 150n and a P gate electrode 150p, the upper surfaces of which may be lower than that of the hard mask layer 123. As a result, at least lower parts of the first and second openings 123n and 123p may be filled with the N and P gate electrodes 150n and 150p. The gate conductive layer may be a poly silicon layer.

A capping material layer (not shown) may be formed on the gate electrodes 150n and 150p so that upper parts of the openings 123n and 123p may be filled with the capping material layer, and the capping material layer may be planarized until an upper surface of the hard mask layer 123 may be exposed. As a result, capping layers 152 may be formed on the gate electrodes 150n and 150p. The capping layers 152 may be silicon oxide layers.

The N-channel epi layer 131 and the N gate electrode 150n may be patterned via the first opening 123n, and thus, the N-channel epi layer 131 may be self-aligned with respect to the N gate electrode 150n. Accordingly, forming a channel only within the N-channel epi layer 131 may be possible, thereby improving electron mobility. However, if the N-channel epi layer 131 may be misaligned with respect to the N gate electrode 150n, a channel may be formed not only in the N-channel epi layer 131 but also in the substrate 100 that may be a silicon layer substrate. Thus, improvement in the electron mobility may be difficult. The term, “align” may be understood that both a center line of the N gate electrode 150n and that of the N-channel epi layer 131 may be arranged in a straight line. Further, the width W_150n of the N gate electrode 150n and the width W_131 of the N-channel epi layer 131 may be substantially equal to each other. The expression, “is substantially equal” may be understood that the width W_150n of the N gate electrode 150n and the width W_131 of the N-channel epi layer 131 may change slightly than as designed during a process.

Likewise, the P gate electrode 150p may be self-aligned with respect to the P-channel epi layer 141. Thus, a channel may be formed only within the P-channel epi layer 141, thereby improving hole mobility. Also, the width W_150p of the P gate electrode 150p and the width W_141 of the P-channel epi layer 141 may be substantially equal to each other.

Referring to FIG. 2H, the hard mask layer 123 and the pad oxide layer 121 may be removed in order to expose sidewalls of the gate electrodes 150n and 150p and parts of the substrate 100 around the gate electrodes 150n and 150p. A lower spacer insulating layer 161 may be deposited on the gate electrodes 150n and 150p and the substrate 100. The lower spacer insulating layer 161 may be a silicon oxide layer.

A third photoresist pattern (not shown) may be formed to cover the PMOS region. N type impurities may be implanted into the N active region 103n by using the third photoresist pattern and the N gate electrode 150n as a mask. As a result, a pair of N source/drain extensions ne may be formed parts of the N active region 103n, which may be exposed around the N gate electrode 150n. The N source/drain extensions ne may be connected to both sides of the N-channel epi layer 131. The n type impurities may contain phosphorus (P), arsenic (As) or antimony (Sb).

The third photoresist pattern may be removed, and a fourth photoresist pattern (not shown) may be formed to cover the NMOS region. P type impurities may be implanted into the P active region 103p by using the fourth photoresist pattern and the P gate electrode 150p as a mask. As a result, a pair of P source/drain extensions pe may be formed in parts of the P active region 130p, which may be exposed around the P gate electrode 150p. The P source/drain extensions pe may be connected to the both sides of the P-channel epi layer 141. The p type impurities may contain boron (B).

Referring to FIG. 2I, an L type upper spacer 161a may be obtained by forming an upper spacer insulating layer (not shown) on the lower spacer insulating layer 161 (as shown in FIG. 2H), forming an upper spacer 163 by anisotropically etching the upper spacer insulating layer, and then etching the lower spacer insulating layer 161 by using the upper spacer 163 as a mask. The upper spacer 163 may be a silicon nitride layer SiNₓ or a silicon oxynitride layer SiON.

Thereafter, a fifth photoresist pattern (not shown) may be formed on the PMOS region in order to expose the NMOS region. N type impurities may be ion implanted into the N active region 130n (as shown in FIG. 1A) by using the fifth photoresist pattern, the N gate electrode 150n, and the spacers 161a and 163 along a sidewall of the N gate electrode 150n as a mask. Then, a pair of N source/drain regions nsd, e.g., a pair of n type impurities diffusion regions, may be formed in a part of a N active region, which may be exposed around the spacers 161a and 163. The N source/drains nsd and the N-channel epi layer 131 may be separate from each other, and N source/drain extensions ne may be present in an active region between the N source/drains nsd and the N-channel epi layer 131. The n type impurities may contain phosphorus (P), arsenic (As) or antimony (Sb).

A sixth photoresist pattern (not shown) may be formed on the NMOS region in order to expose the PMOS region. P type impurities may be implanted in the P active region 130p (as shown in FIG. 1A) by using the sixth photoresist pattern, the P gate electrode 150p and the spacers 161a and 163 along the sidewall of the P gate electrode 150p as a mask. As a result, a pair of P source/drains P source/drain regions psd, e.g., a pair of p type impurities diffusion regions, may be formed in the part of the P active region 130p, which may be exposed around the spacers 161a and 163. The P source/drains psd and the P-channel epi layer 141 may be separate from each other, and P source/drain extensions pe may be present in an active region between the P source/drains psd and the P-channel epi layer 141. The p type impurities may contain boron (B).

Referring to FIG. 2J, the capping layers 152 may be removed in order to expose the gate electrodes 150n and 150p. A high melting point metal conductive layer (not shown) may be deposited on the substrate 100, and the substrate may be annealed. As a result, a plurality of silicide layers 193 may be formed in upper regions of the N gate electrode 150n, the N source/drain diffusion region nsd, the P gate electrode 150p, and the N source/drain diffusion region psd. The high melting point metal conductive layer may be a cobalt (Co) layer or a nickel (Ni) layer.

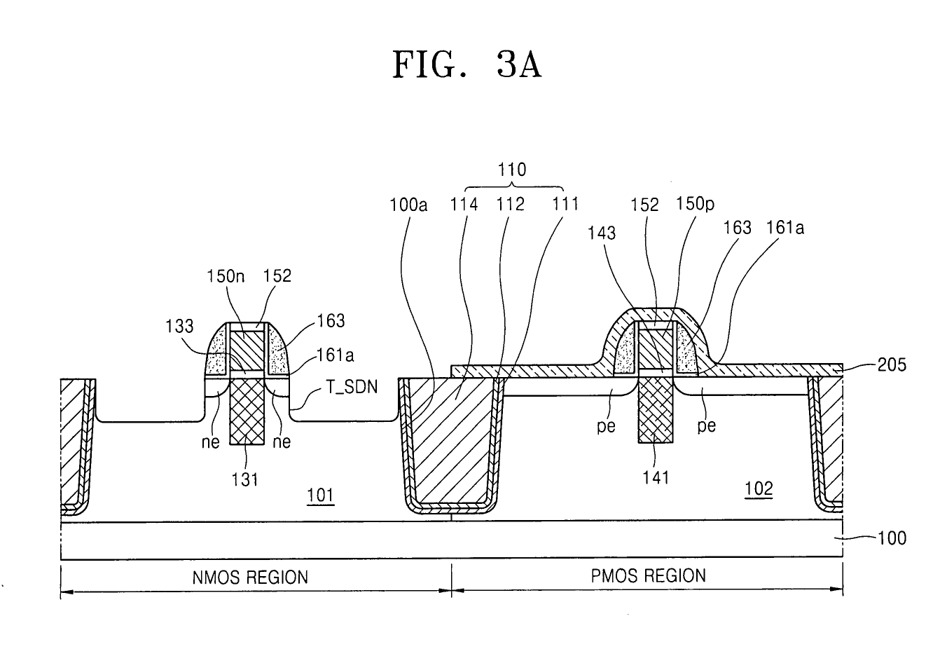

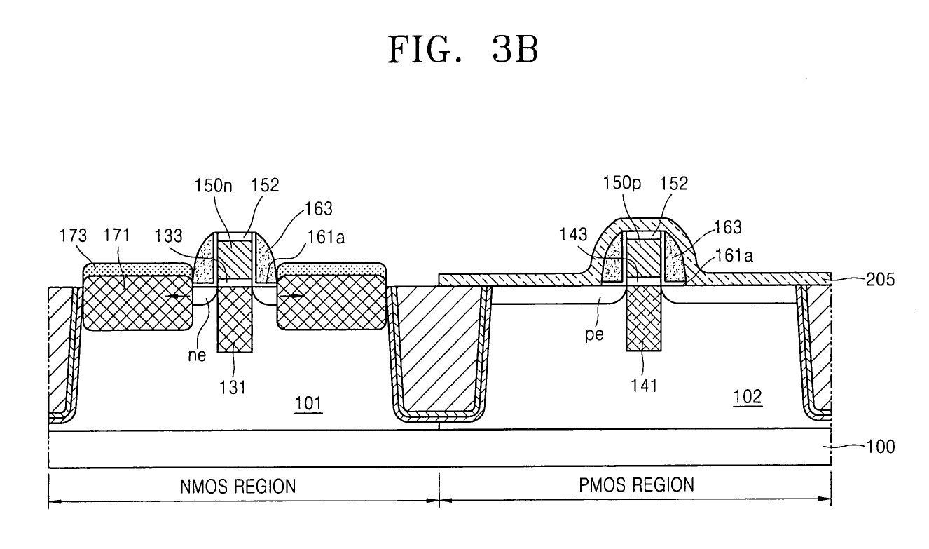

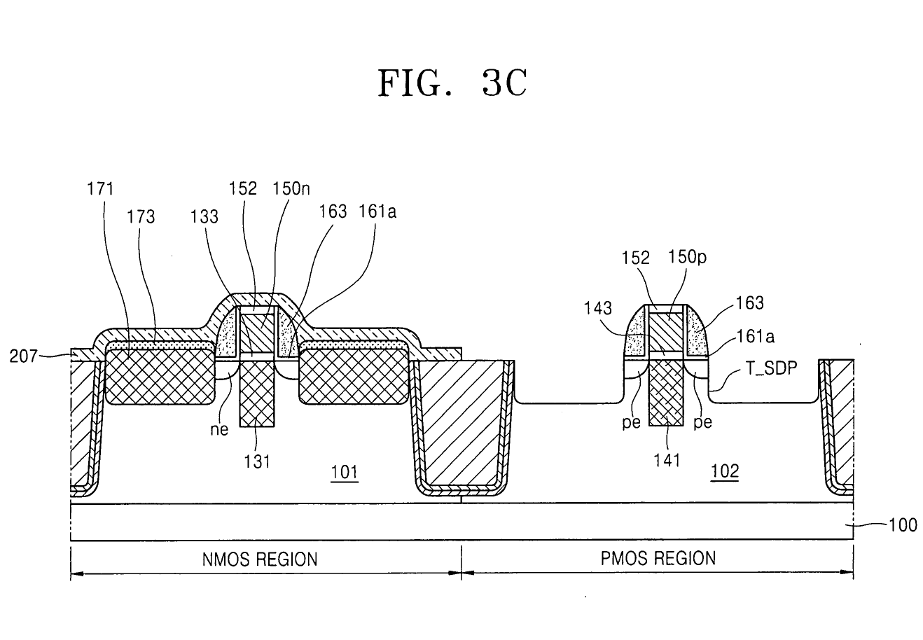

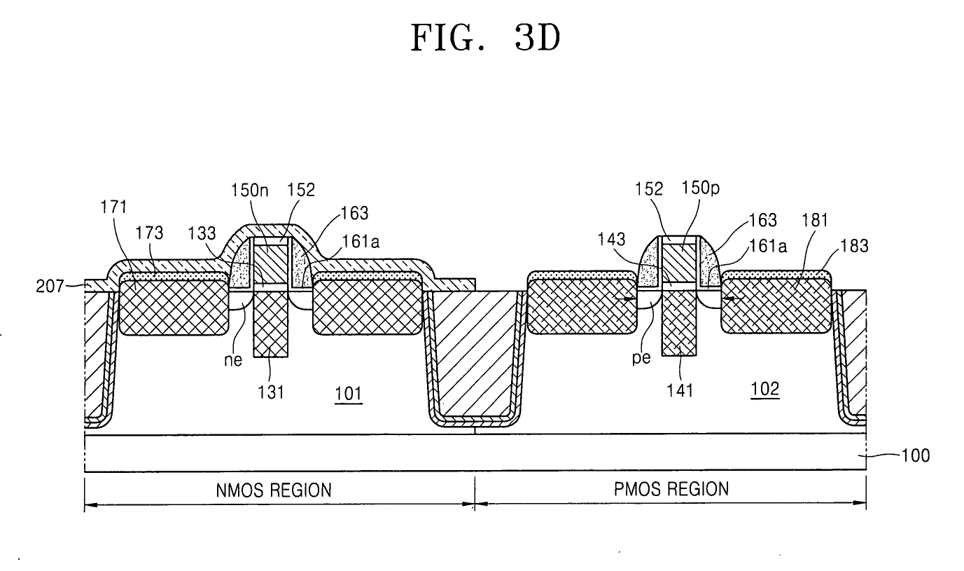

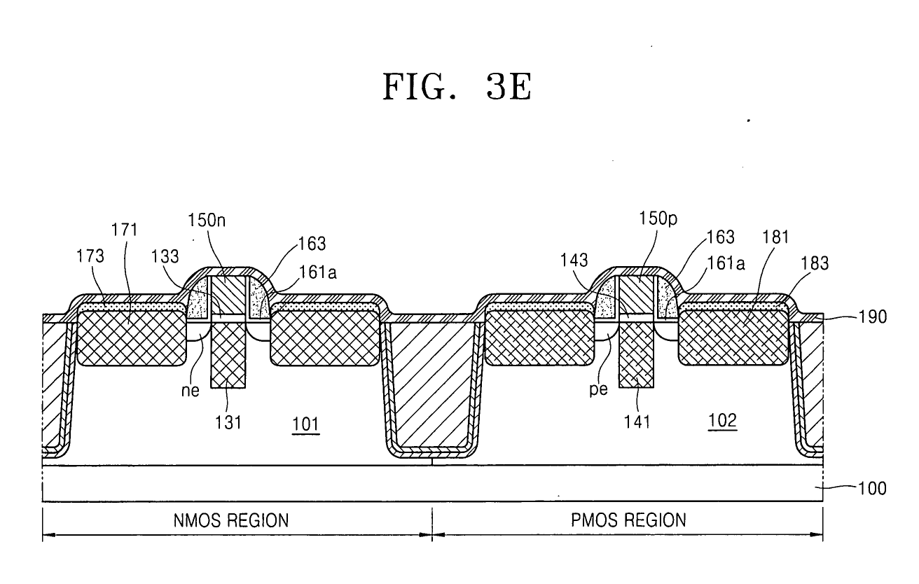

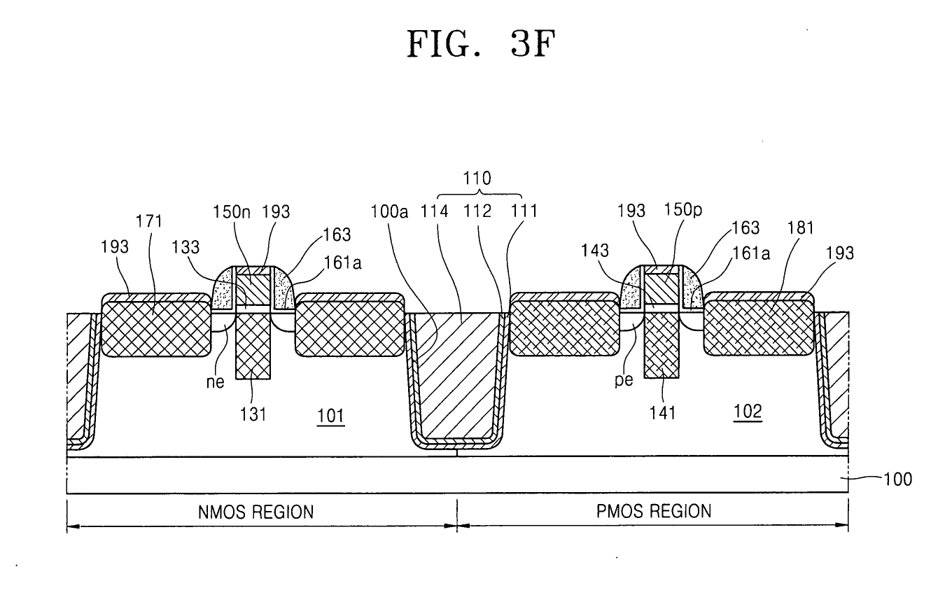

FIGS. 3A-3F are cross-sectional views sequentially illustrating a method of fabricating a CMOS transistor according to example embodiments. The method may be performed as described above with reference to FIGS. 2A-2H. Referring to FIG. 2H and FIG. 3A, an L type lower spacer 161a may be obtained by forming an upper spacer insulating layer on a lower spacer insulating layer 161 (as shown in FIG. 2H), forming an upper spacer 163 by anisotropically etching the upper spacer insulating layer, and etching the lower spacer insulating layer 161 by using the upper spacer 163 as a mask. The lower spacer 161a may be a silicon oxide layer, and the upper spacer 163 may be a silicon nitride layer or a silicon oxynitride layer.

A first mask pattern 205 may be formed on a PMOS region in order to expose an NMOS region. The first mask pattern 205 may be a silicon oxide layer, a silicon nitride layer, or a composite layer thereof, and may be formed to a thickness of about 100 Å to about 150 Å. An N active region may be etched using the first mask pattern 205, an N gate electrode 150n, and spacers 161a and 163 as a mask. As a result, a pair of N source/drain trenches T_SDN may be formed in the N active region. In example embodiments, a capping layer 152 formed on the N gate electrode 150n may prevent or reduce the N gate electrode 150n from being damaged. The N source/drain trenches T_SDN may be formed to a depth of about 300 Å to about 1200 Å. The N source/drain trenches T_SDN may be formed using anisotropic etching. In example embodiments, the sidewalls of the N source/drain trenches T_SDN may have a rough vertical profile.

Referring to FIG. 3B, a pair of N source/drain epi layers 171 may be formed in the N source/drain trenches T_SDN. The N source/drain epi layers 171 may be tensilely strained epi layers. The tensilely strained N source/drain epi layers 171 may be nearly spaced apart from both sides of the N-channel epi layer 131 and thus may apply tensile stress on the N-channel epi layer 131. Accordingly, the N-channel epi layer 131 may be still more tensilely strained, thereby improving the electron mobility in the N-channel epi layer 131. The N source/drain epi layers 171 may be a SiC epi layer that may be epitaxially grown from a part of a substrate 100, which may be exposed via the N source/drain trench T_SDN. The SiC epi layers may have a crystal lattice smaller than that of silicon included in the substrate 100, and thus, may be tensilely strained.

The N source/drain epi layers 171 may be grown in such a manner that upper surfaces thereof may be higher than or may be level with that of an N active region below the N gate electrode 150n. Further, the N source/drain epi layers 171 may be grown in such a manner that upper surfaces thereof may be higher than or may be level with that of the gate oxide layer 133. For example, the N source/drain epi layers 171 may be grown so that the upper surfaces thereof may be higher than the upper surface of the gate oxide layer 133 by about 50 Å to about 100 Å. Therefore, the N source/drain epi layers 171 may more effectively tensilely strain the N-channel epi layer 131.

The insides of the N source/drain epi layers 171 may be doped with n type impurities. For example, n type impurities may be doped in-situ when forming the N source/drain epi layers 171 or be doped ex-situ after forming the N source/drain epi layers 171. As a result, the N source/drain epi layers 171 may function as N sources/drains. The N source/drain epi layers 171 and the N-channel epi layer 131 may be separate from another, and N source/drain extensions ne may be present in an active region between the N source/drain epi layers 171 and the N-channel epi layer 131. The n type impurities may contain phosphorus (P), arsenic (As) or antimony (Sb).

An N source/drain silicon cap 173 may be formed on the N source/drain epi layers 171. The silicon cap 173 may be formed to a thickness of about 30 Å to about 300 Å. The N source/drain epi layers 171 and the silicon cap 173 may be formed using selective epi growing and may be continuously formed in the same epi growing equipment.

Referring to FIG. 3C, the first mask pattern 205 may be removed, and a second mask pattern 207 may be formed on the NMOS region in order to expose the PMOS region. The second mask pattern 207 may be a silicon oxide layer, a silicon nitride layer or a composite layer thereof, and may be formed to a thickness of about 100 Å to about 150 Å. The P active region may be etched using the second mask pattern 207, a P gate electrode 150p, and the spacers 161a and 163 as a mask. As a result, a pair of P source/drain trenches T_SDP may be formed in the P active region. In example embodiments, the capping layer 152 formed on the P gate electrode 150p may prevent or reduce the P gate electrode 150p from being damaged. The P source/drain trenches T_SDP may be formed to a depth of about 300 Å to about 1200 Å. The P source/drain trenches T_SDP may be formed using anisotropic etching. In example embodiments, the sidewalls of the P source/drain trenches T_SDP may have a rough vertical profile.

Referring to FIG. 3D, the second mask pattern 207 may be removed, and a pair of P source/drain epi layers 181 may be formed in the P source/drain trenches T_SDP. The P source/drain epi layers 181 may be compressively strained epi layers. The compressive strained P source/drain epi layers 181 may be nearly spaced apart from both sides of the P-channel epi layer 141, and thus, may apply tensile stress on the P-channel epi layer 141. Accordingly, the P-channel epi layer 141 may be still more compressively strained, thereby improving the hole mobility in the P-channel epi layer 141. The P source/drain epi layers 181 may be a SiGe epi layer that may be epitaxially grown from a part of the substrate 100, which may be exposed via the P source/drain trench T_SDP. The SiGe epi layers may have a crystal lattice greater than that of silicon included in the substrate, and thus, may be compressively strained.

The P source/drain epi layers 181 may be grown in such a manner that upper surfaces thereof may be higher than or may be level with an upper surface of the P active region below the P gate electrode 150P. Further, the P source/drain epi layers 181 may be grown in such a manner that upper surfaces thereof may be higher than or may be level with an upper surface of the P gate oxide layer 143. For example, the P source/drain epi layers 181 may be grown so that the upper surfaces thereof may be higher than that of the P gate oxide layer 143 by about 50 Å to about 100 Å. Accordingly, the P source/drain epi layers 181 may more effectively tensilely strain the P-channel epi layer 141.

The insides of the P source/drain epi layers 181 may be doped with p type impurities. In detail, p type impurities may be doped in-situ when forming the P source/drain epi layers 181 or be doped ex-situ after forming the P source/drain epi layers 181. As a result, the P source/drain epi layers 181 may function as P sources/drains. The P source/drain epi layers 181 and the P-channel epi layer 141 may be separated from one another, and P source/drain extensions pe may be present in an active region between the P source/drain epi layers 181 and the P-channel epi layer 141. The p type impurities may contain boron B. P source/drain silicon caps 183 may be formed on the P source/drain epi layers 181. The silicon caps 183 may be formed to a thickness of about 30 Å to about 300 Å. The P source/drain epi layer 181 and the silicon cap 183 may be formed using selective epi growing and may be continuously formed in the same epi growing equipment.

Referring to FIG. 3E, the second mask pattern 207 may be removed in order to expose the N source/drain silicon caps 173, and the gate capping layers 152 may be removed in order to the gate electrodes 150n and 150p. A high melting point metal conductive layer 190 may be deposited on the substrate 100, and the substrate 100 may be annealed. The high melting point metal conductive layer 190 may be a cobalt (Co) layer or a nickel (Ni) layer.

Referring to FIG. 3F, silicide layers 193 may be formed in upper regions of the N gate electrode 150n and the P gate electrode 150p, the N source/drain silicon caps 173, and the P source/drain silicon caps 183. The silicide layers 193 in the source/drain silicon caps 17 and 183 may contact the N source/drain epi layers 171 and the P source/drain epi layers 181. Thereafter, part of the high melting point metal conductive layer 190, which does not react, may be removed as illustrated in FIG. 3E.

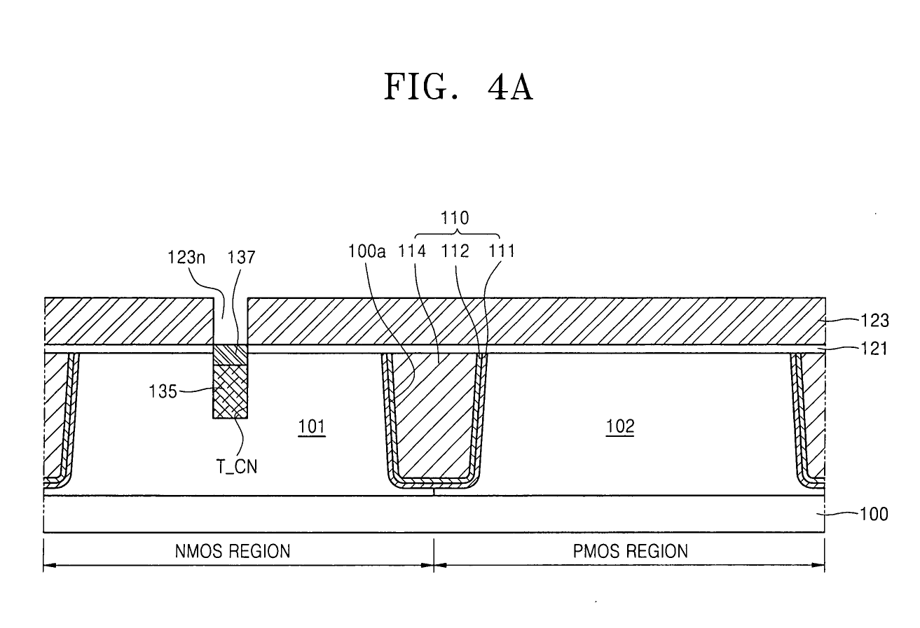

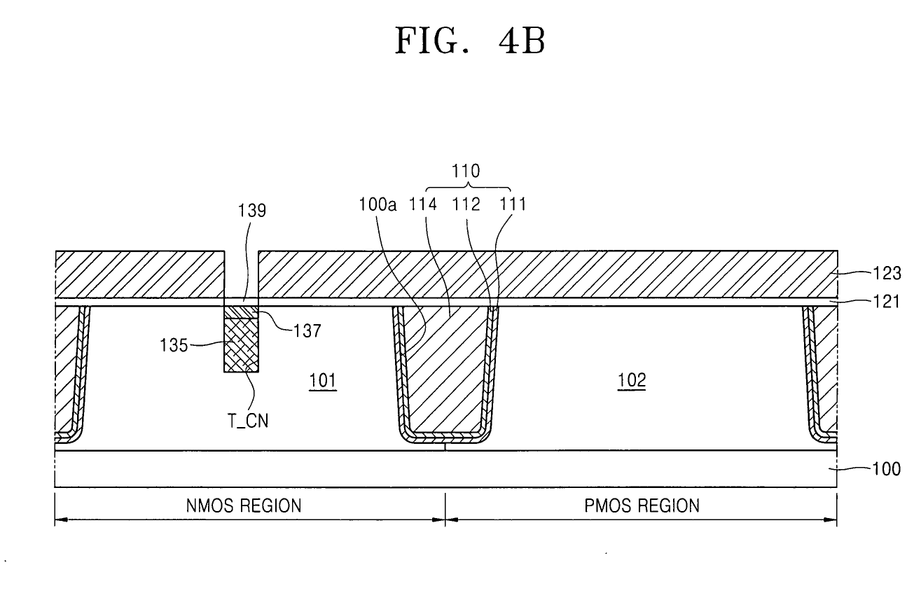

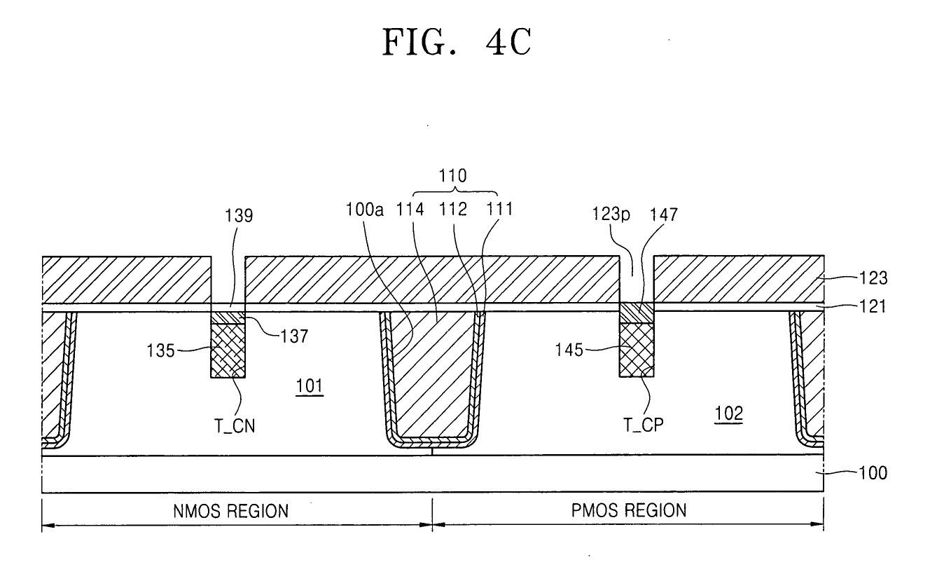

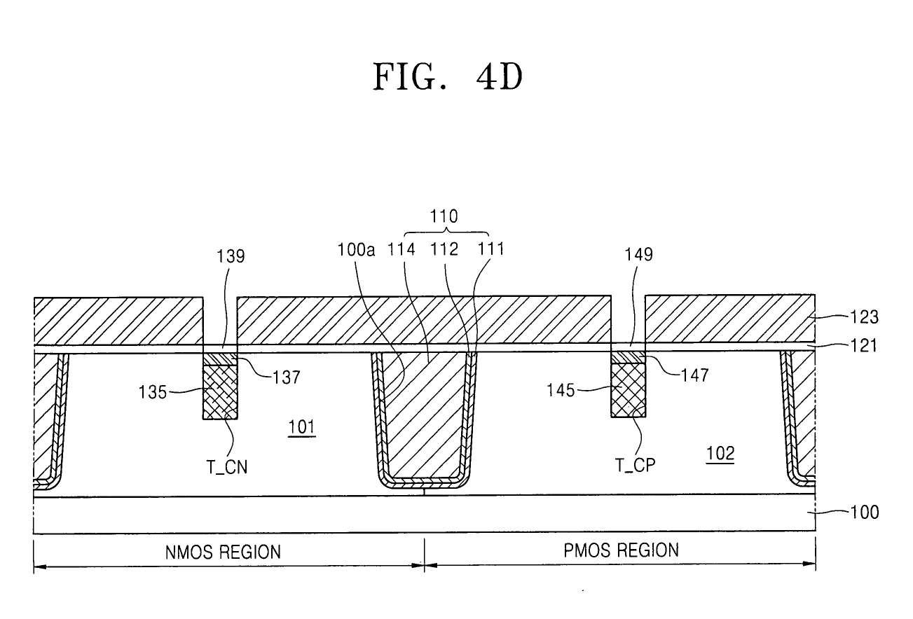

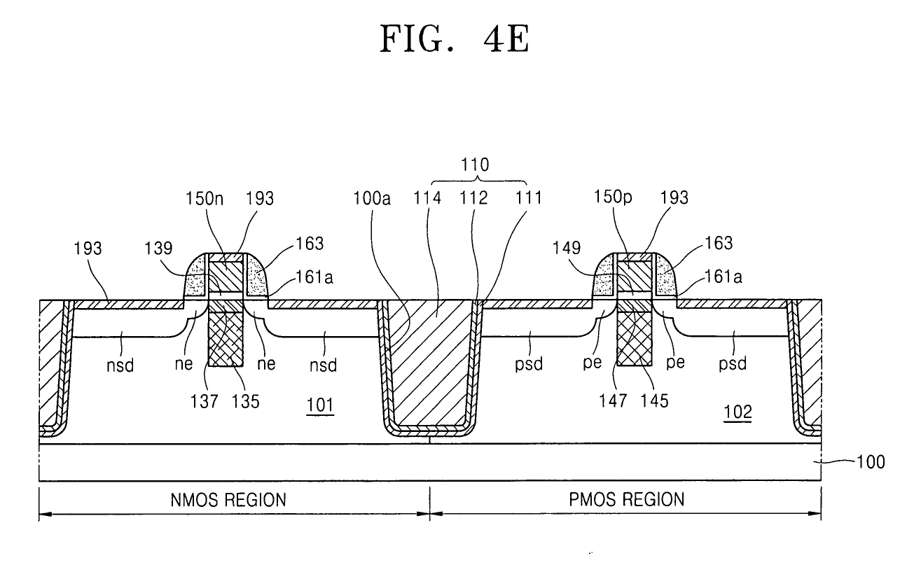

FIGS. 4A-4E are cross-sectional views sequentially illustrating a method of fabricating a CMOS transistor according to example embodiments. The method according to example embodiments may be similar to the method described above with reference to FIGS. 2A through 2J except for the following descriptions. Referring to FIG. 4A, a tensile strain inducing epi layer 135 and a tensilely strained N-channel epi layer 137 may be sequentially formed. The tensile strain inducing epi layer 135 may be a SiGe epi layer that may be epitaxially grown from a part of a substrate 100, which may be exposed via an N-channel trench T_CN. The N-channel epi layer 131 may be a Si epi layer that may be epitaxially grown from a SiGe epi layer. The SiGe epi layer may have a crystal lattice greater than that of silicon included in the substrate 100, and thus, may be compressively strained. The Si epi layer may be tensilely strained by applying tensile stress thereon.

A lower surface of the N-channel epi layer 137 may be lower than a channel region of an NMOS transistor, and an upper surface of the N-channel epi layer 137 may be higher than an upper surface of an N active region. The epi layers 135 and 137 may be formed using selective epi growing and may be continuously formed in the same epi growing equipment.

Referring to FIG. 4B, an N gate oxide layer 139 may be obtained by thermally oxidizing an upper part of the N-channel epi layer 137. A lower surface of the N gate oxide layer 139 may contact the resultant N-channel epi layer 137. An upper surface of the resultant N-channel epi layer 137 may be substantially level with an upper surface of the N active region.

Referring to FIG. 4C, a compressive strain inducing epi layer 145 and a compressively strained P-channel epi layer 147 may be sequentially formed in a P-channel trench T_CP. The compressive strain inducing epi layer 145 may be a SiC epi layer that may be epitaxially grown from a part of the substrate 100, which may be exposed via the P-channel trench T_CP. The P-channel epi layer 147 may be a Si epi layer that may be epitaxially grown from the compressive strain inducing epi layer 145. The SiC epi layer may have a crystal lattice smaller than that of silicon in the substrate 100 and may be tensilely strained. The P-channel epi layer 147 may be compressively strained by applying compressive stress thereon.

A lower surface of the P-channel epi layer 147 may be lower than a channel region of a PMOS transistor, and an upper surface of the P-channel epi layer 147 may be higher than an upper surface of the P active region. The epi layers 145 and 147 may be formed using selective epi growing and may be continuously formed in the same epi growing equipment.

Referring to FIG. 4D, a P gate oxide layer 149 may be obtained by thermally oxidizing an upper part of the P-channel epi layer 147. A lower surface of the P gate oxide layer 149 may contact the resultant P-channel epi layer 147. An upper surface of the resultant P-channel epi layer 147 may be substantially level with the upper surface of the P active region. Thereafter, the method may be performed as described above with reference to FIGS. 2G through 2H, thereby obtaining the CMOS transistor illustrated in FIG. 4E.

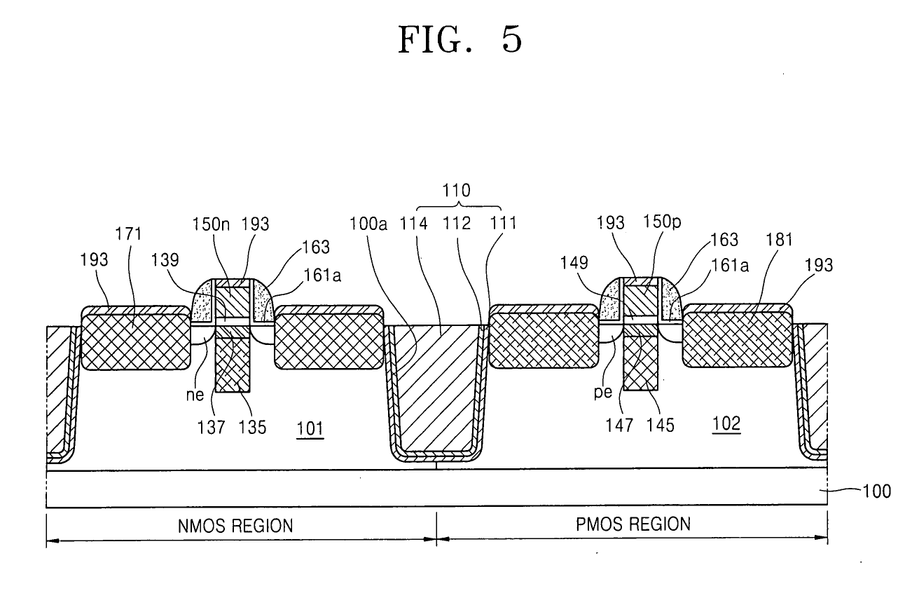

FIG. 5 is a cross-sectional view illustrating a CMOS transistor according to example embodiments. Referring to FIG. 5, a tensile strain inducing epi layer 135, an N-channel epi layer 137, an N gate oxide layer 137, a compressive strain inducing epi layer 145, a P-channel epi layer 147 and a P gate oxide layer 149 may be formed as described above with reference to FIGS. 4A-4D. Thereafter, the CMOS transistor illustrated in FIG. 5 may be obtained by performing a process as described above with reference to FIGS. 3A-3F.

As described above, according to above example embodiments, increasing carrier mobility may be possible by forming a strained epi layer below a gate electrode. Further, reducing manufacturing costs of a channel epi layer may be possible by forming a channel trench and selectively forming a channel epi layer in the channel trench. The channel epi layer may be formed to be self-aligned with respect to the gate electrode, thereby improving the carrier mobility. Also, source/drain epi layers may be formed along both sides of the channel epi layer in order to apply stress on the channel epi layers, thereby improving still more the carrier mobility in the channel epi layer.

While example embodiments have been particularly shown and described with reference to example embodiments thereof, it will be understood by those skilled in the art that various changes in form and details may be made therein without departing from the spirit and scope of the appended claims.

What is claimed is:

1. A metal oxide semiconductor (MOS) transistor comprising:
at least one active region defined by an isolation structure in a substrate;
at least one channel trench in a part of the at least one active region;
at least one strained channel epi layer in the at least one channel trench;
at least one gate electrode aligned on the at least one strained channel epi layer; and
a plurality of sources/drains in the at least one active region along both sides of the at least one strained channel epi layer.

2. The MOS transistor of claim 1, wherein the width of the at least one gate electrode is substantially equal to the width of the at least one strained channel epi layer.

3. The MOS transistor of claim 1, further comprising:
source/drain extensions in the at least one active region between the plurality of sources/drains and the at least one channel epi layer,
wherein the at least one strained channel epi layer is separate from the plurality of sources/drains.

4. The MOS transistor of claim 1, wherein the plurality of sources/drains are N sources/drains, and the at least one channel epi layer is a tensilely strained epi layer.

5. The MOS transistor of claim 4, wherein the tensilely strained epi layer is a SiC epi layer.

6. The MOS transistor of claim 1, wherein the plurality of sources/drains are P sources/drains, and the at least one channel epi layer is a compressively strained epi layer.

7. The MOS transistor of claim 6, wherein the compressively strained epi layer is a SiGe epi layer.

8. The MOS transistor of claim 1, further comprising:
a strain inducing ei layer formed below the at least one channel epi layer in the at least one channel trench.

9. The MOS transistor of claim 8, wherein the at least one channel epi layer is a Si epi layer, and the strain inducing epi layer is a SiGe epi layer.

10. The MOS transistor of claim 8, wherein the at least one channel epi layer is a Si epi layer, and the strain inducing epi layer is a SiC epi layer.

11. The MOS transistor of claim 1, further comprising:
a plurality of source/drain trenches in the at least one active region along both sides of the at least one channel epi layer,
wherein the plurality of sources/drains are source/drain epi layers in the plurality of source/drain trenches.

12. The MOS transistor of claim 11, wherein the source/drain epi layers are doped with n type impurities and are tensilely strained epi layers.

13. The MOS transistor of claim 12, wherein the tensilely strained epi layers are SiC epi layers.

14. The MOS transistor of claim 11, wherein the source/drain epi layers are doped with p type impurities and are compressively strained epi layers.

15. The MOS transistor of claim 14, wherein the compressively strained epi layers are SiGe epi layers.

16. A complementary metal oxide semiconductor (CMOS) transistor comprising at least two of the MOS transistors of claim 1, wherein the at least two MOS transistors are at least one n-type MOS transistor and at least one p-type MOS transistor, and wherein:
the at least one active region is at least one N active region and at least one P active region;
the at least one channel trench is an N-channel trench and a P-channel trench in parts of the at least one N active region and the at least one P active region, respectively;
the at least one channel epi layer is a tensilely strained N-channel epi layer in the N-channel trench and a compressively strained P-channel epi layer in the P-channel trench;
the at least one gate electrode is an N gate electrode and a P gate electrode aligned on the N-channel epi layer and the P-channel epi layer, respectively; and
the plurality of sources/drains are N sources/drains in the at least one N active region along both sides of the N-channel epi layer, and P sources/drains in the at least one P active region along both sides of the P-channel epi layer.

17. The CMOS transistor of claim 16, further comprising:
N source/drain extensions in the at least one N active region between the N sources/drains and the N-channel epi layer,
wherein the N-channel epi layer is separated from the N sources/drains.

18. The CMOS transistor of claim 16, further comprising:
P source/drain extensions in the at least one P active region between the P sources/drains and the P-channel epi layer,
wherein the P-channel epi layer is separated from the P sources/drains.

19. The CMOS transistor of claim 16, further comprising:
a stress strain inducing epi layer below the N-channel epi layer in the N-channel trench.

20. The CMOS transistor of claim 16, further comprising:
a compressive strain inducing epi layer below the P-channel epi layer in the P-channel trench.
